(19) United States
(12) Patent Application Publication
(10) Pub. No.: US 2020/0211841 A1
(43) Pub. Date: Jul. 2, 2020

(54) EPITAXIAL GROWTH SUBSTRATE, METHOD OF MANUFACTURING EPITAXIAL GROWTH SUBSTRATE, EPITAXIAL SUBSTRATE, AND SEMICONDUCTOR DEVICE

(71) Applicant: KABUSHIKI KAISHA TOSHIBA, Minato-ku (JP)

(72) Inventor: Hiroki HIRAGA, Saitama (JP)

(73) Assignee: KABUSHIKI KAISHA TOSHIBA, Minato-ku (JP)

(21) Appl. No.: 16/812,561

(22) Filed: Mar. 9, 2020

Related U.S. Application Data
(63) Continuation of application No. PCT/JP2017/033975, filed on Sep. 20, 2017.

(51) Int. Cl. H01L 21/02; C30B 25/18

(52) U.S. Cl. CPC H01L 21/02293; H01L 21/02485; C30B 25/18

(57) ABSTRACT

An epitaxial growth substrate on an embodiment includes a non-oriented base material and a buffer layer including a metal chalcogenide on the base material. The metal chalcogenide has uniform crystal orientation on a surface of the buffer layer opposite to the base material side. The buffer layer has a thickness of at least 1.0 μm.

### CROSS-REFERENCE TO RELATED APPLICATION

This application is a continuation application based upon and claims the benefit of priority from International Application PCT/JP2017/033975, the International Filing Date of which is Sep. 20, 2017 the entire contents of which are incorporated herein by reference.

### FIELD

Embodiments described herein relate generally to an epitaxial growth substrate, a method of manufacturing epitaxial growth substrate, an epitaxial substrate, and a semiconductor device.

### BACKGROUND

Devices having single crystal quality (e.g., LEDs, power devices, or compound semiconductor solar cells) have achieved high performance, as being fabricated on a high-quality single crystal substrate. However, the single crystal substrates are costly in energy, time, process steps, materials, and so on, between crystallization and wafer cutting, causing the cost of the single crystal substrate to occupy a large part of the entire manufacturing cost and impeding spreading of the devices and instruments.

If a single crystal quality device can be made using an inexpensive plate material such as a glass substrate, great contribution to the reduction of the manufacturing cost and thus widespread of the electronic devices can be expected. However, the surface of an inexpensive plate material such as a glass substrate is amorphous, has a random orientation, and is polycrystalline, thus impeding the possibility of fabricating the single crystal quality devices by epitaxial growth. However, by treating the surface of the inexpensive substrate in some way, there is a possibility of inducing orientation of crystals growing the surface to fabricate a device of single crystal quality. Therefore, studies have been made on this possibility, although no practical device has been achieved yet.

Efficiency of group III-V compound solar cells is more than 30% by tandemization, causing a great expectation for widespread, but the cost of GaAs substrate accounts for tens of percent of product cost. To solve this, a technique called epitaxial lift-off has been developed. Before fabricating the device part, a protective layer which is soluble in acid is previously provided on the single crystal substrate, and is lifted off after fabrication to use the single crystal substrate again. However, this complicates the process steps, such as etching and polishing steps, for each device fabrication, and due to the use of acid, the number of times of recycling the substrate is not sufficient. For these reasons, tandemized group III-V compound solar cells are very expensive.

Efforts have also been made to vapor-deposit Ga₂Se₃—In₂Se₃ compound as a buffer layer on a silicon (111) substrate and heteroepitaxially grow a group III-V compound solar cell thereon. The in-plane triangular lattice of the (0001)-oriented Ga₂Se₃—In₂Se₃ compound crystal has a lattice constant close to the lattice constant of the (111) plane triangular lattice of the GaAs compound to allow orientation of a high quality crystal. This, however, is not a decisive low cost fabrication method, because the vapor deposition steps for forming a composition gradient increases and, in the first place, the epitaxial Si substrate is expensive.

It is possible to form LEDs and let the LEDs emit by disposing a graphene sheet over an inexpensive glass substrate and epitaxially growing GaN on the graphene sheet. However, the lattice constant is largely different between the graphene sheet and the in-plane lattice constant of the c-axis oriented GaN, causing issues in lifetime and light emission characteristics of the device. It is also necessary to uniformly fabricate the graphene sheet over a large area, so that this is currently a costly method.

Meanwhile, a method of using a nanosheet of, for example, layered oxides or metal chalcogenides is disposed on an inexpensive glass substrate and used as a substrate for crystal growth. However, the nanosheet to be fabricated is thin and having a width in a range from a few μm to a few mm at most, so that it is impossible to prepare a substrate having in-plane crystal orientation with a necessary inch size required for mass production. In the method of overlapping a large number of nanosheets while enlarging the area, many defects occur to degrade the performance of various devices. Therefore, this method cannot be used in practice.

Meanwhile, forming a stripe-shaped grooves on the inexpensive substrate and fabricating a zinc oxide transparent electrode with a crystal orientation corresponding to the stripe shape has succeeded. The electrode fabricated by this method, however, has an extremely wide full width at half maximum of the diffraction peak according to in-plane X-ray measurement. The stripe period is in 100 μm-level size, and there is a large separation in the A (angstrom) level period among elements in the crystal. This method is effective if the required crystal quality is not high, such as in the transparent electrode application, but this technique does not assume the use for the epitaxial crystal growth substrate.

### BRIEF DESCRIPTION OF THE DRAWINGS

FIG. 1 is a conceptual diagram of an epitaxial growth substrate according to an embodiment;

FIG. 2 is a cross-sectional image of an epitaxial growth substrate photographed with a scanning electron microscope according to the embodiment;

FIG. 3 is a four-axis X-ray measurement result of the epitaxial growth substrate according to the embodiment;

FIG. 4 is a flowchart of a method of manufacturing the epitaxial growth substrate according to the embodiment;

FIG. 5 illustrates process steps of the method of manufacturing the epitaxial growth substrate according to the embodiment;

FIG. 6 is a conceptual diagram of the epitaxial substrate according to the embodiment;

FIG. 7 is a conceptual diagram of a semiconductor device according to the embodiment;

FIG. 8 is a conceptual diagram of the semiconductor device according to the embodiment;

FIG. 9 is a conceptual diagram of the semiconductor device according to the embodiment; and

FIG. 10 is a conceptual diagram of the semiconductor device according to the embodiment.

### DETAILED DESCRIPTION

An epitaxial growth substrate on an embodiment includes a non-oriented base material and a buffer layer including a metal chalcogenide on the base material. The metal chalcogenide has uniform crystal orientation on a surface of the buffer layer opposite to the base material side. The buffer layer has a thickness of at least 1.0 μm.

Embodiments of the present disclosure will be described in detail below by referring to the accompanying drawings. In the following description, the same members and the like are denoted by the same reference numerals, and the explanation of the members and the like once described is omitted as appropriate.

### First Embodiment

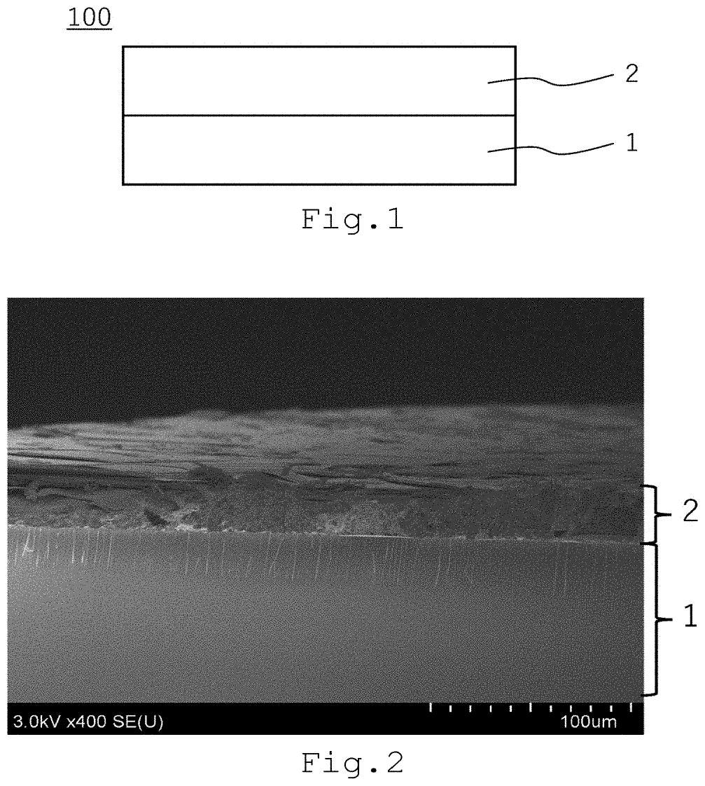

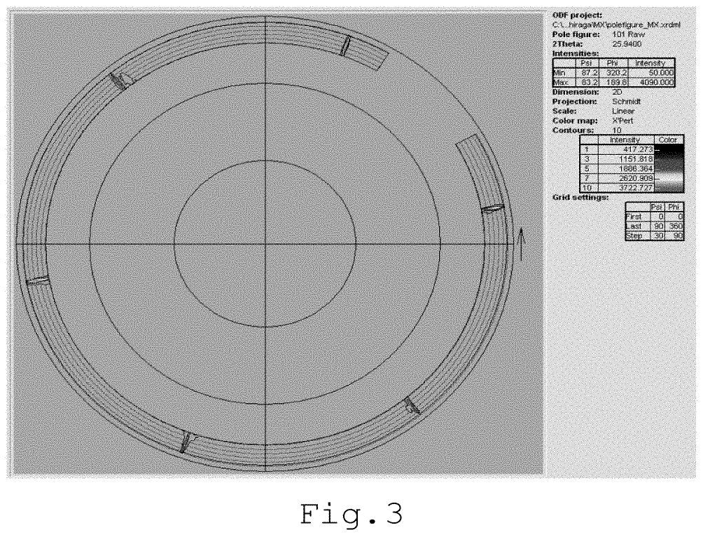

The first embodiment relates to an epitaxial growth substrate. FIG. 1 is a conceptual cross-sectional diagram of an epitaxial growth substrate 100 of the first embodiment. The epitaxial growth substrate 100 illustrated in FIG. 1 includes a base material 1 and a buffer layer 2 existing on the base material 1. FIG. 2 illustrates a cross-section of an image of the epitaxial growth substrate 100 photographed with a scanning electron microscope.

(Substrate)

The base material 1 of the embodiment is a non-oriented base material. The non-oriented base material 1 may be any material on which no crystal orientation is uniquely determined, such as glass, metal, polycrystal, plastic (resin), ceramics, amorphous substances, or the like. The base material 1 is not particularly limited, and any base material that holds the buffer layer 2 which is necessary for epitaxial growth can be used. An expensive single-crystal base material is not used as the base material 1.

(Buffer Layer)

The buffer layer 2 of the embodiment is a layer including a metal chalcogenide. A surface of the buffer layer 2 opposite to the base material 1 has a uniform crystal orientation. Epitaxial growth can proceed on the surface of the buffer layer 2 opposite to the base material 1 side. The buffer layer 2 has a surface which is in direct contact with the base material 1. The surface of the buffer layer 2 opposite to the base material 1 side is the surface opposite to the surface of the buffer layer 2 which is in direct contact with the base material 1.

Preferably, the buffer layer 2 has a thickness of at least 1.0 μm. If the thickness of the buffer layer 2 is less than 1 μm, the buffer layer 2 is too thin to allow fabrication of the buffer layer 2 that has a uniform crystal orientation. Such a very thin buffer layer 2 is not preferable in fabrication of the buffer layer 2, because a part of the buffer layer 2 is peeled off together with the single crystal wafer, so that, during the peeling-off, the very thin buffer layer 2 is peeled off from the base material 1 to impede formation of a surface having uniform crystal orientation. Preferably, the thickness of the buffer layer 2 is at least 3 μm, more preferably at least 5 μm, and most preferably at least 10 μm. At the same time, the thickness of the buffer layer 2 preferably does not exceed 300 μm. If the thickness of the buffer layer 2 exceeds 300 μm, the amount of metal chalcogenide included in the buffer layer 2 increases. This is not preferable from the viewpoint of cost. This is because uneven heating is likely to occur in heating during fabrication of the buffer layer 2, if the buffer layer 2 to be fabricated is excessively thick. In particular, it is difficult to uniformize the crystal orientation in a surface having an area of more than a centimeter square. For example, such an excessively thick buffer layer 2 is not preferable in the case of a large area epitaxial growth substrate, such as a 300 mm wafer. More preferably, the thickness of the buffer layer 2 is at least 1.0 μm and does not exceed 100 μm.

The thickness of the buffer layer 2 is defined as follows. As the inexpensive non-oriented base material 1 can be selected from various materials whose flatness varies from relatively high flatness of glass substrates to locally irregular flatness of sintered ceramics base materials. In fabricating the epitaxial growth substrate 100, the metal chalcogenide is melted and sufficiently filled in irregular gaps of the base material 1. Since the single crystal wafer to be a model of the crystal lattice is a highly flat base material, the cleaved epitaxial growth substrate 100 has a flatness close to that of a single crystal wafer. In this case, the thickness of the buffer layer 2 equals a vertical distance from the surface of the buffer layer 2 opposite to the base material 1 side to the most indented portion of irregularities. In order to determine the thickness, the side surface of the epitaxial growth substrate needs to be observed with an electron microscope observation image for a width range of about 1 μm to 1,000 μm depending on the thickness of the buffer layer 2.

Preferably, the full width at half maximum of the in-plane diffraction peak in the surface of the buffer layer 2 opposite to the base material 1 side is within a range of 1,000 arc.sec. Observing the pole by four-axis X-ray diffraction on the surface of the buffer layer 2 opposite to the base material 1 side finds a spot-like symmetrical intensity distribution due to the uniform crystal orientation of the metal chalcogenide. If the full width at half maximum of the peak of the intensity distribution is within the range of 1000 arc.sec., the surface of the buffer layer 2 opposite to the base material 1 side is regarded as having crystal quality of a single crystal level. Note that it is more preferable if the surface of the buffer layer 2 opposite to the base material 1 has a higher crystal orientation from a viewpoint of epitaxial growth, so that the full width at half maximum of the in-plane diffraction peak is more preferably within the range of 500 arc.sec. FIG. 3 illustrates a result of four-axis X-ray measurement of the epitaxial growth substrate 100 of the embodiment. The definition of the in-plane orientation of the metal chalcogenide is determined by four-axis X-ray diffraction. When the epitaxial growth substrate 100 is viewed from above, if the epitaxial growth substrate 100 is circular, square, or the like, about three points of the center and diagonal points, and midpoints between the center point and the outer periphery may be arbitrarily measured. It is only necessary to measure the inverse pole figure of the in-plane diffraction peak (e.g., (10-11)) to confirm that the pole is symmetric, e.g., highly symmetric such as six-fold symmetry. FIG. 3 illustrates a result of four-axis X-ray measurement of the epitaxial growth substrate 100 of the embodiment. In the pole figure of FIG. 3, six-fold symmetry is confirmed. The full width at half maximum of the pole is about 500 arc.sec.

The buffer layer 2 may include an additive that maintains the metal chalcogenide structure. The buffer layer 2, if including impurities that disturbs maintenance of the metal chalcogenide structure, adversely affects the crystal orientation of the surface of the buffer layer 2 opposite to the base material 1 side. Preferably, therefore, the buffer layer 2 is a layer consisting of a metal chalcogenide. Note that impurities may sometimes be included inevitably in the buffer layer 2 made of a metal chalcogenide.

The surface of the buffer layer 2 on the base material 1 side may not have uniform crystal orientation. As illustrated in FIG. 2, the surface of the buffer layer 2 on the base material 1 side is not a surface to be grown epitaxially, the metal chalcogenide included in the surface does not have to have the uniform crystal orientation. Meanwhile, in the internal region of the buffer layer 2 opposite to the base material 1 side, an amorphous metal chalcogenide, a polycrystalline chalcogenide, or an amorphous chalcogenide and a polycrystalline chalcogenide may be included from the surface of the buffer layer 2 on the base material 1 side to a depth of 0.5 μm. Such an internal region of the buffer layer 2 does not affect epitaxial growth. If the buffer layer 2 has an overall uniform crystal orientation, the buffer layer on the inexpensive base material 1 is likely to be peeled off entirely during peeling off from the single crystal wafer. For these reasons, the internal region of the buffer layer 2 preferably includes an amorphous metal chalcogenide, a polycrystalline chalcogenide, or an amorphous chalcogenide and a polycrystalline chalcogenide.

The metal chalcogenide is a compound of a metal and at least a kind of element selected from the group consisting of Se, S, and Te. The metal chalcogenide is in the form of a two-dimensional sheet spreading in the plane direction. The lattice constant of the metal chalcogenide can arbitrarily be changed by changing the elements to be selected. By changing the composition of the metal chalcogenide, it is possible to match the lattice constant of the single crystal layer subjected to the epitaxial growth with the lattice constant of the metal chalcogenide. In other words, the composition of the metal chalcogenide may be changed according to the single crystal layer to be epitaxially grown and the crystal orientation to be grown, so that a substrate suitable for epitaxial growth of SiC, epitaxial growth of GaN, or the like can be prepared. The plane orientation to be grown can also be adjusted. In addition to the SiC layer or the GaN layer, any single crystal layer that can be grown and adjustable with a metal chalcogenide can be used. The single crystal layer that can be grown also includes, for example, a semiconductor layer made of GaAs, InN, AlN, or the like. The single crystal layer is not particularly limited, and is at least a single crystal layer selected from the group consisting of semimetals, such as Si and Ge, and various oxides and compounds.

Preferably, a difference between a lattice constant (lattice constant of the crystal orientation in the direction of epitaxial growth) of the single crystal layer to be epitaxially grown and a lattice constant of the metal chalcogenide on the surface of the buffer layer 2 opposite to the base material 1 side ([lattice constant of single crystal layer to be epitaxially grown]−[lattice constant of metal chalcogenide on the surface of the buffer layer 2 opposite to the base material 1 side]/[lattice constant of the single crystal layer to be epitaxially grown]) is preferably within ±(plus or minus) 1.0%. A large difference in the lattice constant disturbs epitaxial growth, and a large displacement stops epitaxial growth. More preferably, therefore, the difference between the lattice constant of the single crystal layer to be epitaxially grown and the lattice constant of the metal chalcogenide on the surface of the buffer layer 2 on the side opposite to the base material 1 is within ±0.5%. The lattice constant is obtained by four-axis X-ray diffraction measurement.

Preferably, the metal chalcogenide includes at least a kind of metal selected from the group consisting of Ti, Zr, Hf, V, Nb, Ta, Cr, Mo, W, Zn, Cd, Ga, In, Ge, Sn, Pt, Au, Cu, Ag, Mn, Fe, Co, Ni, Pb, and Bi.

Regarding the two-dimensional sheet-like metal chalcogenide, the surface opposite to the base material 1 may be formed by a plurality of two-dimensional sheet-like metal chalcogenides. At this time, the surface opposite to the base material 1 side is arranged so that the crystal orientations of a plurality of two-dimensional sheet-like metal chalcogenides are aligned. The plurality of two-dimensional sheet-like metal chalcogenides may overlap each other, or may include a stepped portion, as illustrated in FIG. 2. The epitaxial grown is possible so long as the crystal orientations of the metal chalcogenides of a plurality of two-dimensional sheets are aligned, even when the surface opposite to the base material 1 side may not be a metal chalcogenide of a two-dimensional sheet in peeling off from the single crystal wafer. Since the epitaxial growth is possible even when the sheet-like material is not perfectly in the sheet-like shape, the epitaxial growth substrate of the embodiment can be provided at low cost.

An example of metal chalcogenide suitable for growing a SiC, GaN, or GaAs wafer is described. As described below, a suitable metal chalcogenide can be obtained by adjusting the combination of elements of the metal chalcogenide depending on the wafer.

For example, Cr_{0.96}Sn_{0.04}S₂ is used as the metal chalcogenide for the substrate for growing an epitaxial SiC wafer having the plane orientation(0001). Accordingly, the a-axis length of SiC is 3.073 Å and the a-axis length of the metal chalcogenide is 3.073 Å, resulting in 0.0% error which is suitable for the epitaxial growth of SiC.

For example, MoSe_{1.6}S_{0.4} is used as the metal chalcogenide for the substrate for growing an epitaxial GaN wafer having the plane orientation(0001). Accordingly, the a-axis length of GaN is 3.189 Å and the a-axis length of the metal chalcogenide is 3.189 Å, resulting in 0.0% error which is suitable for the epitaxial growth of GaN.

For example, In_{0.99}Ga_{0.01}Se is used for the metal chalcogenide for the substrate for growing an epitaxial GaAs wafer having the plane orientation (111). Accordingly, the a-axis length of GaAs (111) plane is 3.997 Å and the axis length of the triangular lattice of the metal chalcogenide is 3.997 Å, resulting in 0% error which is suitable for the epitaxial growth of GaAs.

### Second Embodiment

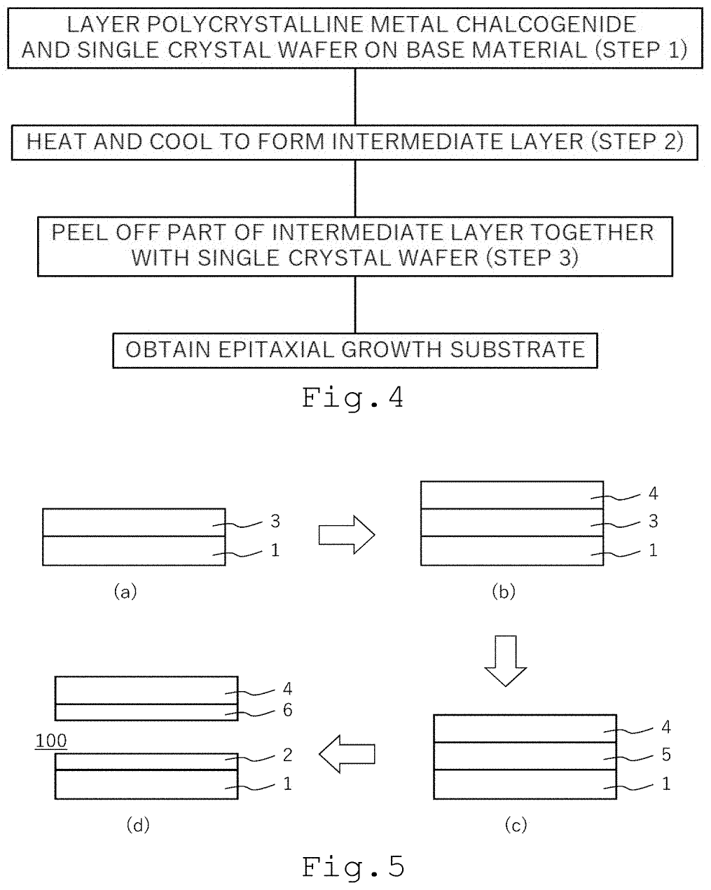

A second embodiment relates to a method for manufacturing an epitaxial growth substrate. FIG. 4 is a flowchart of a method of manufacturing an epitaxial growth substrate. FIGS. 5A to 5D illustrate process steps of the method of manufacturing the epitaxial growth substrate. The method of manufacturing the epitaxial growth substrate is described below according to the process steps of FIGS. 4 and 5. An epitaxial growth substrate manufactured in the second embodiment is identical to the epitaxial growth substrate of the first embodiment.

A method of manufacturing an epitaxial growth substrate of the second embodiment which provides an epitaxial growth substrate 100 on which a buffer layer 2 having a thickness of at least 1.0 μm exists on a base material 1, including

layering a polycrystalline metal chalcogenide 3 and a single crystal wafer 4 in this order on the non-oriented base material 1, the single crystal wafer 4 having a lattice constant difference within ±1.0% relative to the lattice constant of the polycrystalline metal chalcogenide 3 (step 1),

after heating and cooling, forming an intermediate layer 5 between the base material 1 and the single crystal wafer 4 (step 2), and

peeling off a part of the intermediate layer 5 together with the single crystal wafer (step 3). Using the obtained epitaxial growth substrate 100, heteroepitaxial growth can be carried out to fabricate a target epitaxial substrate.

The polycrystalline metal chalcogenide 3 is provided on the base material 1 described in the first embodiment (FIG. 5A). Preferably, the polycrystalline metal chalcogenide 3 is a thin film or powder. A thin film of the polycrystalline metal chalcogenide 3 can be formed by vapor deposition or sputtering.

Accordingly, the base material 1, the polycrystalline metal chalcogenide 3, and the single crystal wafer 4 are layered in this order (FIG. 5B). Preferably, the single crystal wafer 4 is a wafer having a lattice constant difference within ±1.0% relative to the lattice constant of the polycrystalline metal chalcogenide 3. The target epitaxial substrate to be fabricated is used as a template for the single crystal wafer 4.

The polycrystalline metal chalcogenide 3 is then heated until melted, and cooled and crystallized to form the intermediate layer 5 of metal chalcogenide crystallized between the base material 1 and the single crystal wafer 4 (FIG. 50). In melting the polycrystalline metal chalcogenide 3, the base material 1 and the single crystal wafer 4 may be pressed together by applying pressure, or an atmosphere to melt the metal chalcogenide 3 may be applied. On the single crystal wafer 4 side of the intermediate layer 5, an epitaxial film (solid phase epitaxy) of the metal chalcogenide maintaining an epitaxial relationship with the crystal lattice of the single crystal wafer 4 is formed. Thus, the metal chalcogenide has a uniform crystal orientation. This is because the lattice constant (plane orientation on the base material 1 side) of the single crystal wafer 4 and the lattice constant of the metal chalcogenide are matched, so that the metal chalcogenide is crystallized using the crystal face of the single crystal wafer 4 as a template. The metal chalcogenide has a two-dimensional sheet-like crystal structure, and the two-dimensional sheet of the metal chalcogenide arranged over the entire crystal face of the single crystal wafer 4 is in contact with the surface of the single crystal wafer 4 on the base material 1 side and is layered in the direction of the base material 1. Preferably, the thickness of the intermediate layer 5 is larger than 1.0 μm, and more preferably larger than 3 μm, 5 μm, or 10 μm. Preferably, the thickness of the intermediate layer 5 is thinner than 350 μm. The elements constituting the metal chalcogenide are appropriately adjusted for the purpose of, for example, increasing or decreasing the melting point, improving peeling ability, improving crystallinity, or improving the crystal lattice matching.

Then, the intermediate layer 5 is cleaved to peel off a part of the intermediate layer 5 together with the single crystal wafer 4, whereby the epitaxial growth substrate 100 including the buffer layer 2 described in the first embodiment having a thickness of at least 1.0 μm on the base material 1 is obtained (FIG. 5D). A part of the intermediate layer 5 becomes the buffer layer 2. The metal chalcogenide is in the two-dimensional sheet-like crystal, and can be cleaved between the sheets. Therefore, the two-dimensional sheet-like crystal of the metal chalcogenide 6 is disposed on both the surface of the buffer layer 2 on the base material 1 side and the surface of the remaining portion of the intermediate layer left on the single crystal wafer 4. Both surfaces may be constituted by a plurality of two-dimensional sheets of metal chalcogenide. A large area substrate capable of epitaxial growth can be formed with not a single two-dimensional sheet. The combination of the single crystal wafer 4 and the polycrystalline metal chalcogenide 3 can be changed according to the substance to be epitaxially grown and the plane orientation. Therefore, the method of manufacturing the epitaxial growth substrate 100 of the embodiment is not limited to the type of epitaxial substrates, such as Si, SiC, GaAs, and Ge. The single crystal wafer 4 is not particularly limited, and is at least a kind of single crystal wafer selected from the group consisting of semimetals, such as Si and Ge, and various oxides and compounds.

The single crystal wafer 4 obtained by cleavage can be reused as the single crystal wafer 4 used for forming the intermediate layer 5. The metal chalcogenide 6 of a part of the intermediate layer 5 left on and in contact with the single crystal wafer 4 can be reused as a material for the intermediate layer 5. Although the single crystal wafer 4 is expensive, the manufacturing cost of the epitaxial growth substrate can be reduced in the second embodiment, because the single crystal wafer 4 can be reused in the method of manufacturing the epitaxial growth substrate. The method of manufacturing the epitaxial growth substrate of the second embodiment is advantageous in that the process steps of the method do not impose a large load on the single crystal wafer 4, so that the number of times of reuse is very large, such as several hundred times or several thousand times.

### Third Embodiment

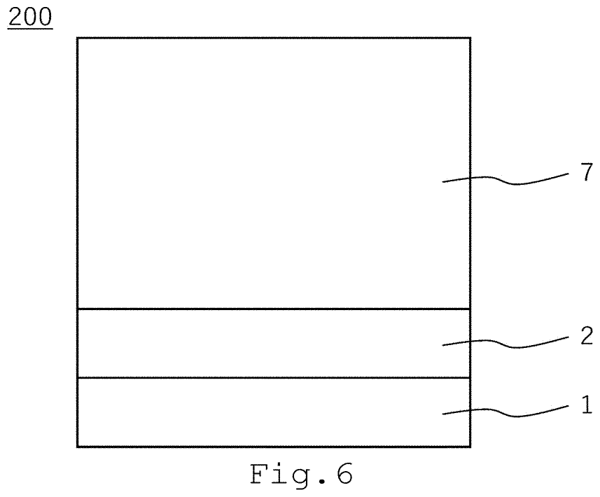

A third embodiment relates to an epitaxial substrate. The epitaxial substrate of the third embodiment is a substrate epitaxially grown using the epitaxial growth substrate 100 of the first embodiment. FIG. 6 illustrates a conceptual diagram of an epitaxial substrate 200 of the third embodiment. The epitaxial substrate 200 in FIG. 6 includes a base material 1, a buffer layer 2, and an epitaxial layer 7.

The base material 1 and the buffer layer 2 are the epitaxial growth substrate 100. The lattice constant of the metal chalcogenide of the surface of the buffer layer 2 opposite to the base material 1 side matches with the lattice constant of the epitaxial layer 7. The lattice constant difference between the lattice constant (plane orientation on the base material 1 side) of the epitaxial layer 7 and the lattice constant of the metal chalcogenide ([lattice constant of the epitaxial layer 7]−[lattice constant of the metal chalcogenide of the buffer layer 2 opposite to the base material 1 side]/[lattice constant of the epitaxial layer 7]) is within 1.0%, and the buffer layer 2 and the epitaxial layer 7 are heteroepitaxial.

The epitaxial layer 7 is a semiconductor layer, such as a SiC layer, a GaAs layer, or a GaN layer, or a superconducting layer such as YBCO. The epitaxial layer 7 is not particularly limited, and may be at least a kind of epitaxial layer selected from the group consisting of semimetals, such as Si and Ge, and various oxides and compounds.

To confirm that the epitaxial substrate 200 uses the epitaxial growth substrate 100 of the embodiment, any four points of the epitaxial substrate 200 need to be observed and measured. When the epitaxial substrate 200 is viewed from above, if the device is circular, square, or the like, about three points of the center and diagonal points, and midpoints between the center point and the outer periphery may arbitrarily be measured. Items to be measured includes observation of a cross-section of the epitaxial substrate 200 with a transmission electron microscope to clarify the film thickness, composition, and so on, and observation of the diffraction peak normal to the film plane or the in-plane diffraction peak of the epitaxial substrate 200 by X-ray diffraction. Accordingly, the epitaxial relationship between the epitaxial layer 7 and the buffer layer 2 can be known.

The base material 1 may be peeled off from the epitaxial substrate 200. Further, the buffer layer 2 can also be removed from the epitaxial substrate 200. For example, in a case where the epitaxial layer 7 is a superconducting layer such as YBCO, the base material 1 and the buffer layer 2 may be removed and an insulating layer may be provided on the epitaxial layer 7, whereby superconducting wiring and superconducting magnets can be fabricated.

### Fourth Embodiment

A fourth embodiment relates to a semiconductor device. FIG. 7 illustrates a conceptual diagram of a semiconductor device 300 of the embodiment. The semiconductor device 300 illustrated in FIG. 7 is a solar cell. The semiconductor device 300 illustrated in FIG. 7 includes a lower electrode 301, a transition metal chalcogenide 302, a p-type GaAs layer 303, an n-type GaAs layer 304, and an upper electrode 305. The transition metal chalcogenide 302, the p-type GaAs layer 303, and the n-type GaAs layer 304 correspond to the epitaxial substrate of the third embodiment. In the fourth embodiment, the base material of the epitaxial substrate may be removed and the lower electrode 301 may be provided. Alternatively, a metal plate may be used as the base material and the metal plate may be used as the lower electrode 301. Since the transition metal chalcogenide 302 is conductive, the transition metal chalcogenide 302 may be provided between the p-type GaAs layer 303 and the lower electrode 301, or the transition metal chalcogenide 302 may be removed. In the fourth embodiment, an epitaxial GaAs layer grown from the epitaxial growth substrate 100 of the embodiment is included. A typical formation of the epitaxial GaAs layer requires a large cost, but since the epitaxial GaAs layer grown from the epitaxial growth substrate 100 of the embodiment can be formed at low cost, the manufacturing cost of the semiconductor device can be lowered. This solar cell may be a multi-junction solar cell.

### Fifth Embodiment

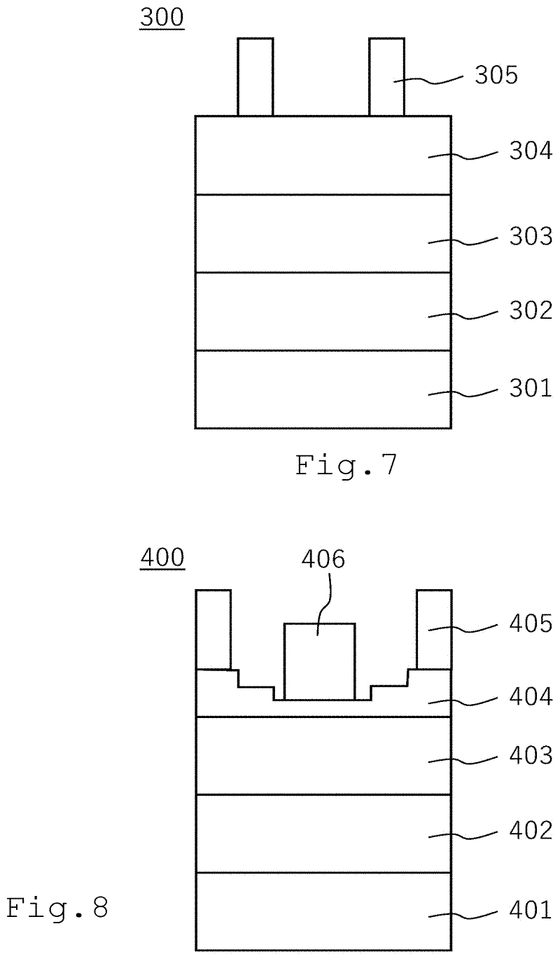

A fifth embodiment relates to a semiconductor device. FIG. 8 illustrates a conceptual diagram of a semiconductor device 400 of the embodiment. The semiconductor device 400 illustrated in FIG. 8 is a high frequency device. The semiconductor device 400 illustrated in FIG. 8 includes an alumina plate 401, a transition metal chalcogenide 402, a semi-insulating GaAs layer 403, an active layer 404, a gate 405, a drain 406, and a source 407. The lattice constant of the transition metal chalcogenide 402 and the lattice constant of the semi-insulating GaAs layer 403 are matched, and the alumina plate 401, the transition metal chalcogenide 402, and the semi-insulating GaAs layer 403 correspond to the epitaxial substrate of the third embodiment. The transition metal chalcogenide 402 may be provided between the semi-insulating GaAs layer 403 and the alumina plate 401, or the transition metal chalcogenide 402 may be removed together with the base material. The fifth embodiment includes an epitaxial GaAs layer grown from the epitaxial growth substrate 100 of the embodiment. A typical formation of the epitaxial GaAs layer requires a large cost, but since the epitaxial GaAs layer grown from the epitaxial growth substrate 100 of the embodiment can be formed at low cost, the manufacturing cost of the semiconductor device can be lowered.

### Sixth Embodiment

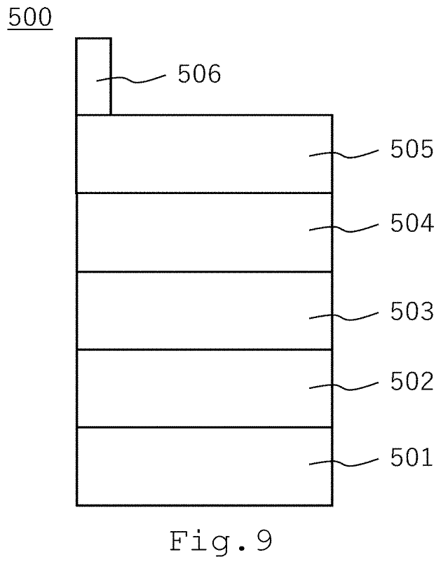

A sixth embodiment relates to a semiconductor device. FIG. 9 illustrates a conceptual diagram of a semiconductor device 500 of the embodiment. The semiconductor device 500 illustrated in FIG. 9 is a light emitting device (LED). The semiconductor device 500 illustrated in FIG. 9 includes a lower electrode 501, a transition metal chalcogenide 502, an n-type GaN layer 503, a quantum well layer 504, a p-type GaN layer 505, and an upper electrode 506. The lattice constant of the transition metal chalcogenide 502 and the lattice constant of the n-type GaN layer 503 are matched, and the lower electrode 501 corresponds to the epitaxial substrate of the third embodiment. In the sixth embodiment, the lower electrode 501 and the transition metal chalcogenide 502 may be removed to form an insulating film. In the sixth embodiment, an epitaxial GaN layer grown from the epitaxial growth substrate 100 of the embodiment is included. A typical formation of the epitaxial GaN layer requires a large cost, but since the epitaxial GaN layer grown from the epitaxial growth substrate 100 of the embodiment can be formed at low cost, the manufacturing cost of the semiconductor device is lowered.

### Seventh Embodiment

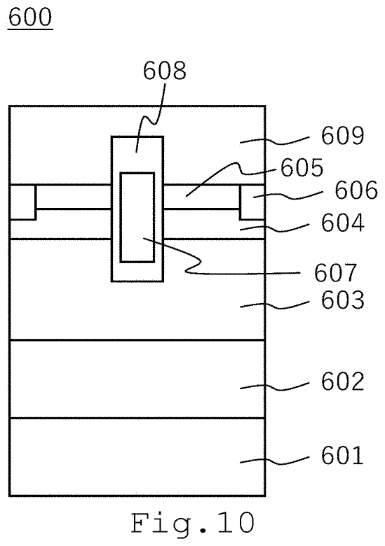

A seventh embodiment relates to a semiconductor device. FIG. 10 illustrates a conceptual diagram of the semiconductor device 600 of the embodiment. The semiconductor device 600 illustrated in FIG. 10 is a trench-type SiC-metal-oxide-semiconductor field-effect transistor (MOSFET). The semiconductor device 600 illustrated in FIG. 10 includes a drain electrode 601, a transition metal chalcogenide 602, an n-type SiC drift layer 603, a p-layer 604, a p+-region 605, an n+-region 606, a gate 607, an insulating film 608, and a source electrode 609. The lattice constant of the transition metal chalcogenide 602 and the lattice constant of the n-type SiC drift layer 603 are matched, and the drain electrode 601, the transition metal chalcogenide 602, the n-type SiC drift layer 603, the p-layer 604, the n+-region 605 and the p+-region 606 correspond to the epitaxial substrate of the third embodiment. Since the transition metal chalcogenide 602 is conductive, the transition metal chalcogenide 602 may be provided between the n-type SiC drift layer 603 and the drain electrode 601, or the transition metal chalcogenide 602 may be removed. The seventh embodiment includes an epitaxial SiC layer grown from the epitaxial growth substrate 100 of the embodiment A typical formation of the epitaxial SiC layer requires a large cost, but since the epitaxial SiC layer grown from the epitaxial growth substrate 100 of the embodiment can be formed at low cost, the manufacturing cost of the semiconductor device is lowered.

Examples and a comparative example are described below.

### Example 1

A glass substrate (Eagle XG) having a thickness of 0.5 mm was prepared as a substrate. On this substrate, a small amount of InSe containing Ga was formed by vapor deposition until a thickness of 50 μm is reached. A GaAs(111) single crystal substrate was layered on the vapor deposited film. This was heated in an electric furnace in argon atmosphere at 1 atmosphere and gradually cooled to dissolve and crystalize InSe. This was taken out of the furnace, and a cutter knife was inserted between the glass substrate and the GaAs (111) single crystal substrate, while keeping the temperature at about 200° C., to peel off the substrates vertically. As a result, an epitaxial growth substrate on which a two-dimensional layered compound was formed on the glass was obtained. The a-axis length of the InSe compound was determined to be 4.000 Å by four-axis X-ray diffraction. Using this as a base material, a GaAs three-junction photoelectric conversion element was fabricated and peeled off from the glass base material after fabrication to form an electrode.

### Example 2

An alumina substrate having a thickness of 0.5 mm was prepared as a substrate. On this substrate, selenide molybdenum sulfide having a thickness of 50 μm and containing about 20% Se was formed by sputtering. A GaN (0001) single crystal substrate was layered on the vapor-deposited film. This was heated and gradually cooled in an electric furnace in argon atmosphere at 10 atmosphere to dissolve and crystallize a selenide molybdenum sulfide compound. This was taken out of the furnace, and a cutter knife was inserted between the alumina substrate and the GaN (0001) single crystal substrate, while keeping the temperature at about 200° C., to peel off the substrates vertically. As a result, an epitaxial growth substrate on which a two-dimensional layered compound was formed on the alumina substrate was obtained. The a-axis length of the selenide molybdenum sulfide compound was determined to be 3.189 Å by four-axis X-ray diffraction. Using this as the base material, a GaN-based light emitting element was fabricated. After fabrication, it was peeled off from the alumina base material to form an electrode. When using a lateral device, it is not necessary to peel off the alumina substrate.

### Example 3

An alumina substrate having a thickness of 0.5 mm was prepared as a substrate. On this substrate, chromium sulfide molybdenum containing about 40% Cr and having a thickness of 50 μm was formed by sputtering. A SiC (0001) single crystal substrate was placed on the vapor-deposited film. This was heated and gradually cooled in an electric furnace in the argon atmosphere at 10 atmosphere to dissolve and crystallize the chromium sulfide molybdenum compound. A cutter knife was inserted between the alumina substrate and the SiC (0001) single crystal substrate, while keeping the temperature to about 200° C., and the substrate was peeled off vertically. As a result, an epitaxial growth substrate on which a two-dimensional layered compound was formed on the alumina substrate was obtained. The a-axis length of the chromium sulfide molybdenum compound was determined to be 3.073 Å by four-axis X-ray diffraction. Using this as the base material, a SiC power device was fabricated. After fabrication, it was peeled off from the alumina base material to form an electrode. When using a lateral device, it is not necessary to peel off the alumina substrate.

### Comparative Example 1

A glass substrate (Eagle XG) having a thickness of 0.5 mm was prepared as a substrate. On this substrate, a small amount of InSe containing Ga was formed by vapor deposition until a thickness of 50 μm is reached. Then, a vapor-deposited film glass substrate was layered. This was heated in an electric furnace in argon atmosphere at 1 atmosphere and gradually cooled to dissolve and crystalize InSe. This was taken out, and a cutter knife was inserted between the glass substrates, while keeping the temperature to about 200° C., and the substrate was peeled off vertically. This was measured by X-ray diffraction (XRD) pattern measurement, and it was found that a two-dimensional layered compound was formed on the glass. The orientation normal to the plane was along the c-axis to some extent, but the in-plane orientation was random and the full width at half maximum was about 10,000. Accordingly, this was not usable as the epitaxial growth substrate.

Here, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An epitaxial growth substrate, comprising:
a non-oriented base material; and
a buffer layer including a metal chalcogenide on the base material, wherein
the metal chalcogenide has uniform crystal orientation on a surface of the buffer layer opposite to the base material side, and
the buffer layer has a thickness of at least 1.0 μm.

2. The substrate according to claim 1, wherein
a full width at half maximum of an in-plane diffraction peak of a surface of the buffer layer opposite to the base material side is within a range of 1000 arc.sec.

3. The substrate according to claim 1, wherein
the buffer layer consist of the metal chalcogenide.

4. The substrate according to claim 1, wherein
the surface of the buffer layer on the base material side includes a metal chalcogenide having non-uniform crystal orientation.

5. The substrate according to claim 1, wherein
the metal chalcogenide is at least a kind of metal selected from the group consisting of Ti, Zr, Hf, V, Nb, Ta, Cr, Mo, W, Zn, Cd, Ga, In, Ge, Sn, Pt, Au, Cu, Ag, Mn, Fe, Co, Ni, Pb, and Bi.

6. The substrate according to claim 1, wherein
the thickness of the buffer layer is at least 1.0 μm and does not exceed 300 μm.

7. A method of manufacturing an epitaxial growth substrate for providing an epitaxial growth substrate on which a buffer layer having a thickness of at least 1.0 μm exists on a base material, the method comprising:
layering a metal chalcogenide and a single crystal wafer in this order on an non-oriented base material, the single crystal wafer having a lattice constant difference within ±1.0% relative to the lattice constant of the metal chalcogenide;
after heating and cooling, forming an intermediate layer between the base material and the single crystal wafer; and
peeling off a part of the intermediate layer together with the single crystal wafer.

8. The method according to claim 7, wherein
pressurization is carried out during the heating.

9. The method according to claim 7, wherein
the metal chalcogenide is melted by the heating.

10. The method according to claim 7, wherein
a thickness of the buffer layer is not larger than 300 μm.

11. The method according to claim 7, wherein
the single crystal wafer peeled off with the part of the intermediate layer is used in forming the intermediate layer.

12. An epitaxial substrate, comprising:
an epitaxial layer; and
a buffer layer including a metal chalcogenide that is in contact with the epitaxial layer according to claim 1, wherein
the metal chalcogenide of the buffer layer on a surface on the epitaxial layer side has uniform crystal orientation, and
the epitaxial layer has a lattice constant difference within ±1.0% relative to the lattice constant of the metal chalcogenide.

13. A semiconductor device, comprising:
an epitaxial semiconductor layer; and
a buffer layer including a metal chalcogenide that is in contact with the epitaxial semiconductor layer according to claim 1, wherein
the metal chalcogenide of the buffer layer on a surface on the epitaxial semiconductor layer side has uniform crystal orientation, and
the epitaxial semiconductor layer has a lattice constant difference within ±1.0% relative to the lattice constant of the metal chalcogenide.

14. The element according to claim 13, wherein
the metal chalcogenide is at least a kind of metal selected from the group consisting of Ti, Zr, Hf, V, Nb, Ta, Cr, Mo, W, Zn, Cd, Ga, In, Ge, Sn, Pb, and Bi.
